(19) United States
(12) Patent Application Publication
(10) Pub. No.: US 2011/0132645 A1
(43) Pub. Date: Jun. 9, 2011

(54) GRANULAR VARISTOR AND APPLICATIONS FOR USE THEREOF

(76) Inventors: Ning Shi, San Jose, CA (US); Robert Fleming, San Jose, CA (US); Junjun Wu, Los Gatos, CA (US); Lex Kosowsky, San Jose, CA (US)

(21) Appl. No.: 12/954,605

(22) Filed: Nov. 24, 2010

Related U.S. Application Data
(60) Provisional application No. 61/266,988, filed on Dec. 4, 2009.

(51) Int. Cl. H05K 1/09; C01G 9/02; C01G 29/00; C01G 41/02; C01B 19/04; B32B 15/04; H01C 17/06

(52) U.S. Cl. 174/257; 423/622; 423/617; 423/606; 423/509; 428/457; 428/469; 428/472; 29/620

(57) ABSTRACT

Embodiments described include a non-polymeric voltage switchable dielectric (VSD) material comprising substantially of a grain structure formed from only a single compound, processes for making same, and applications for using such non-polymeric VSD materials.

### RELATED APPLICATIONS

This application claims benefit of priority to Provisional U.S. Patent Application No. 61/266,988, filed Dec. 4, 2009; the aforementioned provisional application being incorporated by reference in its entirety.

### FIELD OF THE INVENTION

Embodiments described herein pertain to voltage switchable dielectric materials, and more specifically to granular varistors and applications for use thereof.

### BACKGROUND

Voltage switchable dielectric (VSD) materials are materials that are insulative at low voltages and conductive at higher voltages. These materials are typically composites comprising of conductive, semi conductive, and insulative particles in a polymer matrix. These materials are used for transient protection of electronic devices, most notably electrostatic discharge protection (ESD) and electrical overstress (EOS). Generally, VSD material behaves as a dielectric, unless a characteristic voltage or voltage range is applied, in which case it behaves as a conductor. Various kinds of VSD material exist. Examples of voltage switchable dielectric materials are provided in references such as U.S. Pat. No. 4,977,357, U.S. Pat. No. 5,068,634, U.S. Pat. No. 5,099,380, U.S. Pat. No. 5,142,263, U.S. Pat. No. 5,189,387, U.S. Pat. No. 5,248,517, U.S. Pat. No. 5,807,509, WO 96/02924, and WO 97/26665.

### BRIEF DESCRIPTION OF THE DRAWINGS

FIG. 1 illustrates a system for forming a layer of varistor material on a copper or metal foil, according to an embodiment.

FIG. 2 illustrates a process for forming a varistor layer on a target structure, according to one or more embodiments.

FIG. 3A illustrates a substrate device on which a layer of non-polymeric VSD material is formed, in accordance with embodiments.

FIG. 3B illustrates a substrate device in which the varistor layer 312 is embedded between two opposing metal sheets or foils 310, 320.

FIG. 4A illustrates a substrate device that is configured with non-polymeric VSD material, as described with any of the embodiments provided herein.

FIG. 4B illustrates an alternative substrate device configuration utilizing non-polymeric VSD material in which a conductive layer is embedded in a substrate, according to an embodiment.

FIG. 4C illustrates an alternative substrate device configuration utilizing non-polymeric VSD material in which a vertical switching arrangement is provided within the substrate, according to an embodiment.

FIG. 5 is a simplified diagram of an electronic device on which VSD material in accordance with embodiments described herein may be provided.

FIG. 6 illustrates a wafer substrate device utilizing non-polymeric VSD material for transient electrical protection, according to an embodiment.

FIG. 7 is a top view of a package portion of a discrete device with a lead frame design, which incorporates non-polymeric VSD material as a protected element against transient electrical events, according to an embodiment.

FIG. 8 illustrates a discrete device using a lead frame structure, having an integrated layer of non-polymeric VSD material, according to an embodiment.

FIG. 9 illustrates a discrete device, having an integrated and embedded layer of non-polymeric VSD material, according to an embodiment.

### DETAILED DESCRIPTION

Embodiments described include a non-polymeric voltage switchable dielectric (VSD) material comprised substantially of a grain structure formed from only a single compound, processes for making same, and applications for using such non-polymeric VSD materials.

Varistors are a class of materials that have a significant non-ohmic current voltage characteristic. Such materials are sometimes referred to as voltage switchable dielectric (VSD) materials. As with other VSD materials, varistors have sufficiently high electrical resistance to be considered dielectric or insulative (or an insulator class material) when no electrical field is present. But with application of voltage that exceeds a trigger, the varistor resistance drops significantly, such that the material becomes conductive (or a conductor class material).

Many types of VSD materials, such as described in U.S. patent application Ser. No. 11/829,946, entitled VOLTAGE SWITCHABLE DIELECTRIC MATERIAL HAVING CONDUCTIVE OR SEMI-CONDUCTIVE ORGANIC MATERIAL (incorporated by reference herein); and U.S. patent application Ser. No. 11/829,948, entitled VOLTAGE SWITCHABLE DIELECTRIC MATERIAL HAVING HIGH ASPECT RATIO PARTICLES (incorporated by reference herein); are formed by uniformly dispersing conductor and semiconductor particles in a binder. In contrast, varistors differ from such polymer based VSD materials in that no binder is present. As such, the varistor is non-polymeric VSD material. According to embodiments, a varistor material is provided that is substantially homogeneous or pure in its molecular composition. As used herein, a substantially pure molecular composition means that more than 99% of the stated quantity (e.g. varistor layer) is formed from a particular molecular compound (e.g. zinc oxide, bismuth oxide, tungsten oxide, or cadmium telluride).

VSD materials, including varistors, are used to protect electrical devices from transient electrical events, such as Electrostatic Discharge (ESD) or lightning strike.

Embodiments described herein include various substrate devices (and techniques for forming such devices) comprising a varistor layer that is deposited on a target device. The target device can correspond to a metal or conductive element, such as copper foil or other metal substrate.

In some embodiments, a varistor layer is formed on site, and positioned to be effective in protecting electrical components of a substrate device from transient electrical events such as ESD. For example, a varistor layer may be formed on a metal substrate to protect other electrical elements that are interconnected on the substrate.

Under another embodiment, a metal foil (or sheet) is provided on which grain structures of a selected compound are deposited to create a varistor layer on the foil.

Still further, a thin film deposition process may be implemented to deposit a layer of varistor material on a metal foil or sheet.

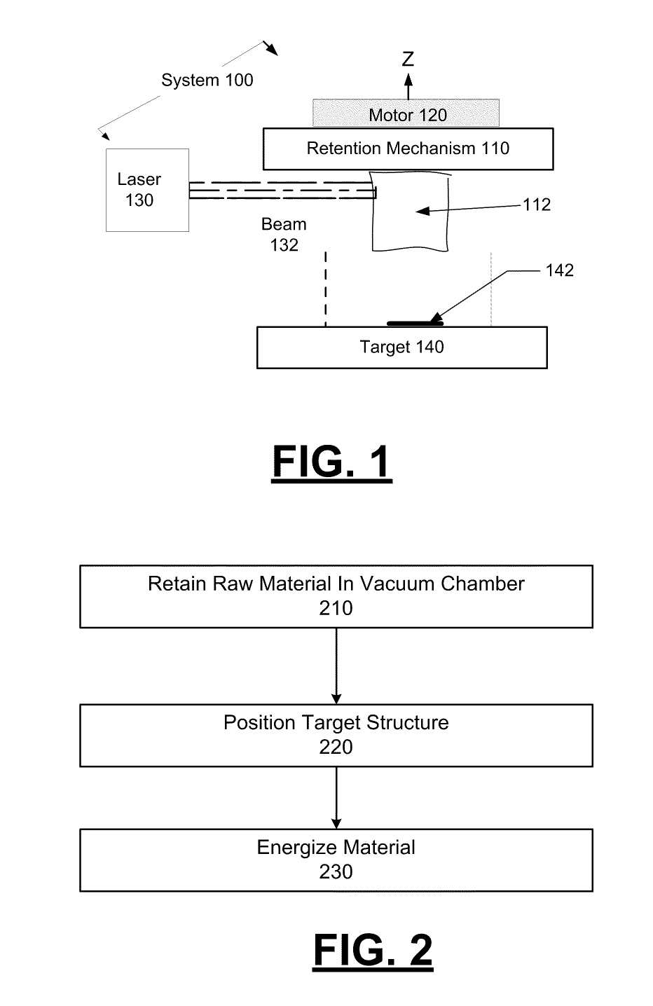

FIG. 1 illustrates a system for forming a layer of varistor material on a copper or metal foil, according to an embodiment. A system 100 is provided by a retention mechanism 110, a motor 120, and a laser 130. The retention mechanism 110 retains a quantity of raw varistor material 112. In the raw state, material 112 is amorphic and lacks the requisite crystalline structure that can exhibit the desired non-ohmic electrical behavior. Thus, in the raw form (or amorphic), the material 112 is not a varistor, but has the potential of forming into a varistor. With application of laser beam 132 (or other form of energy beam), the molecules crystallize and fall to form an aggregation of grain structures. It is believed that the resulting agglomeration of material exhibits non-ohmic electrical characteristic as a result of the molecular boundaries formed in the grain structures.

In one embodiment, the raw varistor material 112 is a mass of zinc oxide. In another embodiment, the raw varistor material 112 is a mass of Bismuth oxide. Other materials (including ceramic metal oxides) may be used, such as Nickel Oxide, Cadmium Telluride and Tungsten Oxide. In some implementations, the raw varistor material 112 can initially be structured in a solid form that can be mechanically gripped and manipulated, so that they can be spun in presence of the laser beam 132, as described below.

A target 140 (e.g. metal sheet) is positioned under the raw varistor material 112 to collect crystals formed from application of the laser. In an implementation shown by FIG. 1, the motor 120 spins the quantity of raw state varistor material 112, while the laser 130 direct the beam 132 onto the material 112. The process of directing the beam 132 onto the spinning quantity of raw material 112 can be performed in a vacuum chamber. The result is that raw material 112 is crystallized at its exterior and peeled off of the mass.

In an embodiment, the laser 130 is a high energy pulsed laser. Other forms of lasers and energy beams may also be used. One criterion for selection of alternative beams is for the beam to have the ability to direct a sufficient amount of energy to the raw state material 112 so that molecular crystals are formed on the exterior of the raw mass and peeled off.

In the vacuum environment, the crystallized molecules fall from the mass of the raw material 112 and agglomerate as a layer or quantity of varistor material 142 at the target 140. The agglomeration of the varistor material 142 is formed without sintering the material when deposited. Under some embodiments, the quantity of varistor material formed on the target 140 under such a process can range between a few nanometers to 300 nanometers. The target 140 can be moved by robot or other mechanism to enable the varistor material 142 to be selectively deposited or patterned. Varistor material 142 is substantially homogenous or pure in its composition, in that it matches the composition of the mass of the raw material 112 (which is assumed to be substantially pure). The varistor material 142 is comprised on the molecular level of grain structures formed by the crystallization of the mass of raw material 112. The non-ohmic electrical characteristic of the resulting material is believed to be the result of the grain structure (and boundaries formed between grains) of the select compound (e.g. zinc oxide).

FIG. 2 illustrates a process for forming a varistor layer on a target structure, according to one or more embodiments. In describing a method of FIG. 2, reference is made to elements of FIG. 1 for purpose of illustrating suitable components or elements for performing a step or sub step being described.

Raw state material 112 is held in a vacuum chamber (210) for subsequent energization by an energy beam. The material may be selected based on its ability to form crystalline molecules when energized that have varistor-like electrical properties. Examples of raw material that can be used include zinc oxide, bismuth oxide, tungsten oxide, or cadmium telluride. The material used may be selected based on the known electrical characteristics of the granularized form of the material. Specific electrical characteristics that impact selection of what material is used include: triggering voltage (the voltage at which the material switches into the conduct of state), clamp voltage or leakage current of the material. As described, the crystalline molecules are deposited on a target location.

The target structure is positioned in the target location of the vacuum chamber (220). Numerous types of structures can be used as a target structure, according to embodiments. In one embodiment, the target structure corresponds to a metallic foil, such as formed by copper, silver, nickel, gold, or chrome. In another embodiment, the target structure corresponds to a substrate for printed circuit board device. Still further, other applications include a wafer substrate on which die elements are provided. In the latter case, the wafer may be positioned in the target location pre-passivation.

The raw state material is then subjected to an energy beam that is sufficient to crystallize its perimeter molecules (230). In the raw state, the molecules of the raw material 112 are relatively amorphic, and application of the energy beam causes individual molecules to crystallize by forming grain structures with boundaries. These molecular structures are agglomerated on that target location with continual application of the energy beam onto the raw material 112, resulting in the granularized molecules falling off the mass of the raw material 112 and onto the target location.

Some embodiments increase the amount of crystals that can be formed by spinning the material 112 relative to the energy beam. According to some embodiments, the raw state material 112 is spun while a high-energy beam is directed onto the material. As an alternative, the beam can also be moved about the raw material 112.

In one embodiment, the high-energy beam corresponds to the laser beam. The high-energy beam provides sufficient energy to cause molecular crystals to drop onto the target location (or the target device positioned in that location). The individual crystallized molecules agglomerate on the target location to form a varistor material. When sufficient varistor material is formed on the target device, the process is complete.

With reference to FIG. 1 and FIG. 2, the following provides an example of an implementation of an embodiment. The high energy beam may be provided as an ultra high energy pulsed beam. The raw material 112 of the varistor may be held in a high vacuum chamber (e.g. under 10EXP-06 Torr) and spun at a relative slow rotation (e.g. 1-10 rotations per minute). The combination of the rotational speed and the high energy laser allow for the exterior layer of the material to heat up. The target location can also moved (rotated and/or translated) to allow for granularized material to fall at desired locations that are distributed (rather than deposited at a single spot). In experimentation, granular structures were formed on a copper plate that was spun and heated to about 200 C.

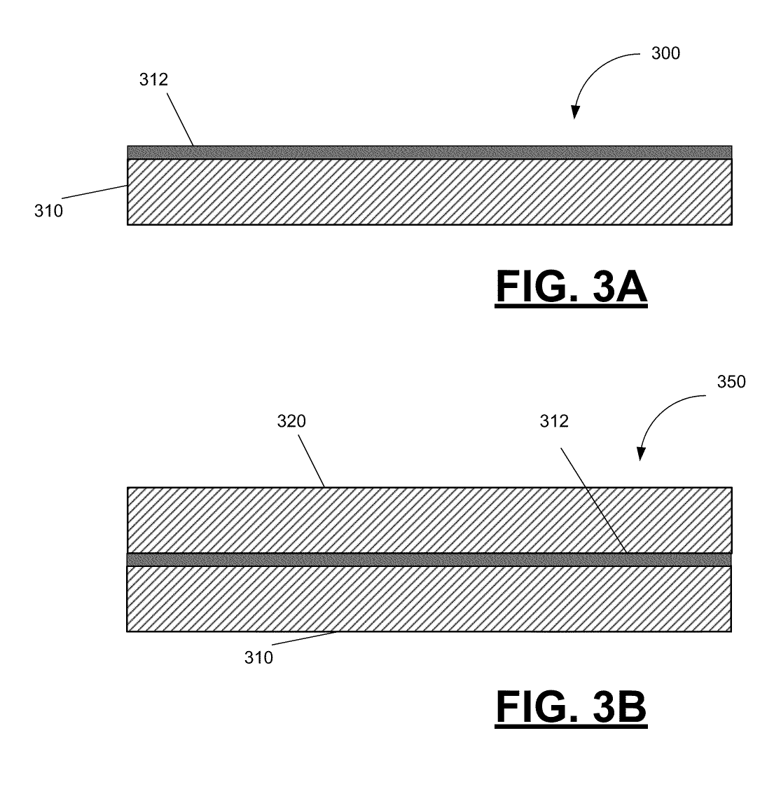

FIG. 3A illustrates a substrate device on which a layer of non-polymeric VSD material is formed, in accordance with embodiments. The substrate device 300 includes a metal sheet 310 or foil (e.g. copper, gold, silver, chrome, brass), although any metallic or conductive component (e.g. leads, backplane, pins) may be used. In some embodiments, the non-polymeric VSD material is formed from varistor material such as described with embodiments of FIG. 1 and FIG. 2. To form varistor, the metal sheet 310 (or other conductive element) may be subjected to a process such as implemented with system 100 (FIG. 1), where the mass of raw material 112 (FIG. 1) is subjected to an energy beam to allow crystals to form on the underlying component. The result is that a layer of varistor material, which can range in thickness (e.g. 2-300 nm), is formed on the metal sheet 310 as part of a production process. As part of a production process, the varistor material 312 is integrally combined with the metal sheet and enables inherent electrical protection for a product that is formed from the metal sheet 310.

In an embodiment of FIG. 3A, the combination of varistor material 312 and substrate 310 form a core for substrate devices such as circuit boards. The core has inherent non-ohmic characteristics that can be used to provide a grounding plane for electrical elements that are subsequently formed on the substrate, when ESD and other transient electrical events occur.

FIG. 3B illustrates a substrate device in which the varistor layer 312 is embedded between two opposing metal sheets or foils 310, 320. Among other applications, the formation enables the substrate device 350 to have an embedded grounding plane that can electrically connect to vias in order to ground electrical elements of the device when an ESD or transient event occurs.

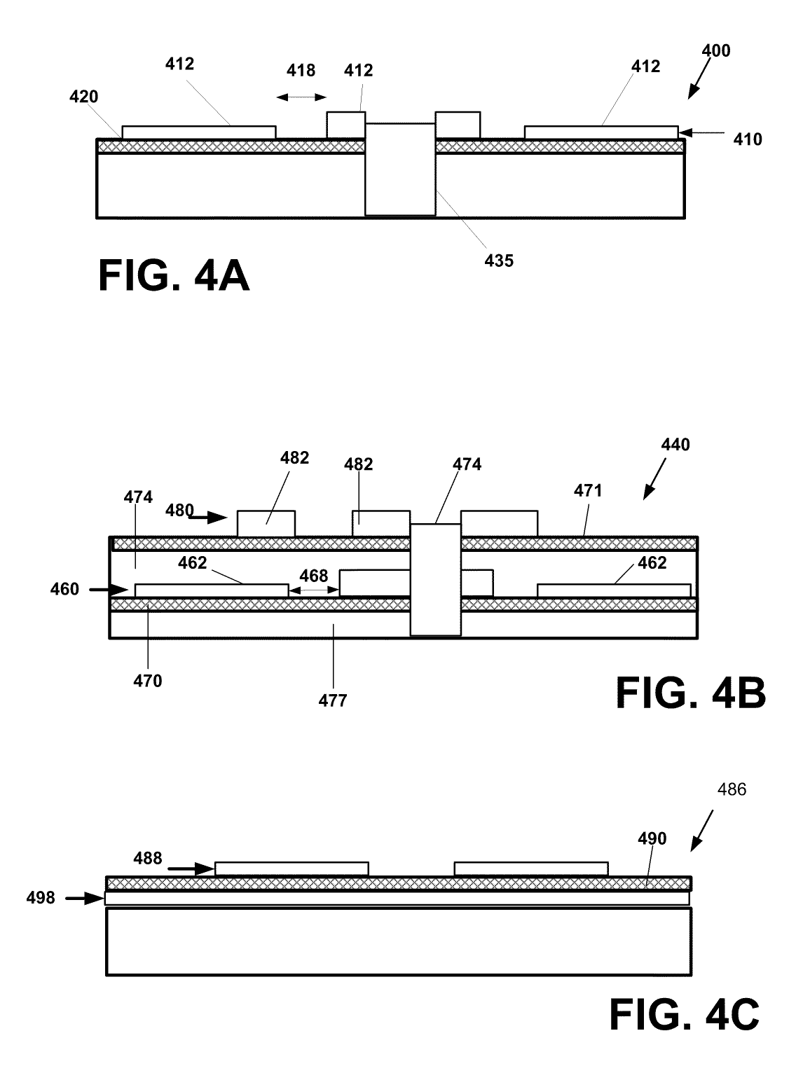

FIG. 4A illustrates device that is configured with non-polymeric VSD material, according to an embodiment. As shown by FIG. 4A, the substrate device 400 corresponds to, for example, a printed circuit board. A conductive layer 410 comprising electrodes 412 and other trace elements or interconnects is formed on a thickness of surface of the substrate 400. In a configuration as shown, non-polymeric VSD material 420 may be provided on substrate 400 (e.g. as part of a core layer structure) in order provide, in presence of a suitable electrical event (e.g. ESD), a lateral switch between electrodes 412 that overlay the VSD layer 420. According to some embodiments, the non-polymeric VSD material is formulated using a deposition process such as described with embodiments of FIG. 1 and FIG. 2. A varistor such as described with preceding embodiments may be used as the non-polymeric VSD material.

The gap 418 between the electrodes 412 acts as a lateral or horizontal switch that is triggered ‘on’ when a sufficient transient electrical event takes place. In one application, one of the electrodes 412 is a ground element that extends to a ground plane or device. The grounding electrode 412 interconnects other conductive elements 412 that are separated by gap 418 to ground as a result of material in the VSD layer 420 being switched into the conductive state (as a result of the transient electrical event).

In one implementation, a via 435 extends from the grounding electrode 412 into the thickness of the substrate 400. The via provides electrical connectivity to complete the ground path that extends from the grounding electrode 412. The portion of the VSD layer that underlies the gap 418 bridges the conductive elements 412, so that the transient electrical event is grounded, thus protecting components and devices that are interconnected to conductive elements 412 that comprise the conductive layer 410.

FIG. 4B illustrates an alternative substrate device configuration utilizing non-polymeric VSD material in which a conductive layer is embedded in a substrate, according to an embodiment. In a configuration shown, a conductive layer 460 comprising electrodes 462 are distributed within a thickness of a substrate 440. A layer of non-polymeric VSD material 470 and dielectric material 474 (e.g. B-stage material) may overlay the embedded conductive layer. Additional layers of dielectric material 477 may also be included, such as directly underneath or in contact with the non-polymeric VSD layer 470. Surface electrodes 482 comprise a conductive layer 480 provided on a surface of the substrate 440. Surface electrodes 482 may also overlay a layer of non-polymeric VSD material 471. One or more vias 474 may electrically interconnect electrodes/conductive elements of conductive layers 460, 480. The layers of non-polymeric VSD material 470, 471 are positioned so as to horizontally switch and bridge adjacent electrodes across a gap 468 of respective conductive layers 460, 480 when transient electrical events of sufficient magnitude reach the VSD material. According to some embodiments, the non-polymeric VSD material is formed from varistor materials, such as described with embodiments of FIG. 1 and FIG. 2. Each of the individual layers of varistor material may be formed from a deposition process such as described with FIG. 1 and FIG. 2. The layers may be assembled onto one another after deposition of the varistor material on the corresponding conductive layer 460, 480.

As an alternative or variation to an embodiment of FIG. 4A and FIG. 4B, FIG. 4C illustrates a vertical switching arrangement for incorporating non-polymeric VSD material into a substrate. A substrate 486 incorporates a layer of non-polymeric VSD material 490 that separates two layers of conductive material 488, 498. In one implementation, one of the conductive layers 498 is embedded. When a transient electrical event reaches the layer of non-polymeric VSD material 490, it switches conductive and bridges the conductive layers 488, 498. The vertical switching configuration may also be used to interconnect conductive elements to ground. For example, the embedded conductive layer 498 may provide a grounding plane.

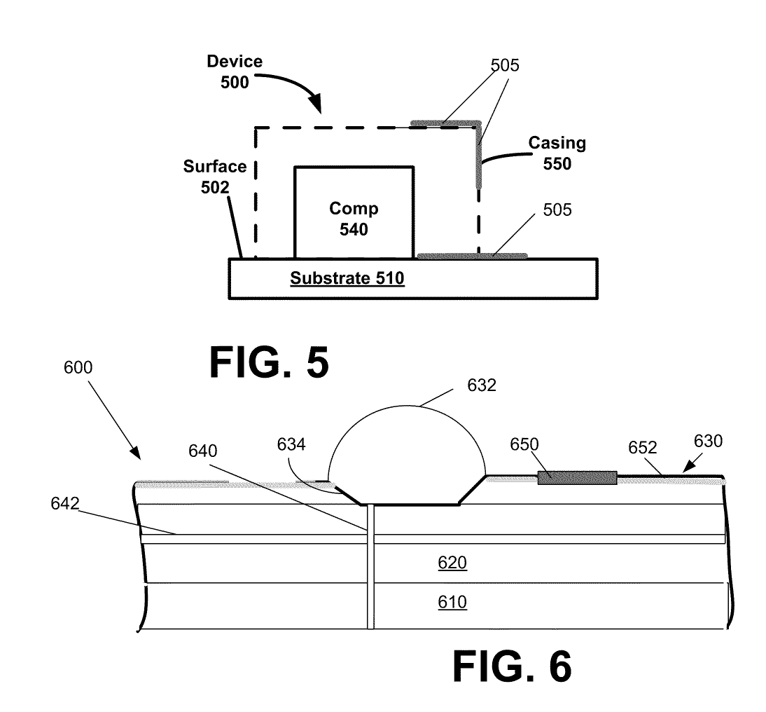

FIG. 5 is a simplified diagram of an electronic device on which non-polymeric VSD material in accordance with embodiments described herein may be provided. FIG. 5 illustrates a device 500 including substrate 510, component 540, and optionally casing or housing 550. VSD material 505 (in accordance with any of the embodiments described) may be incorporated into any one or more of many locations, including at a location on a surface 502, underneath the surface 502 (such as under its trace elements or under component 540), or within a thickness of substrate 510. Alternatively, the non-polymeric VSD material may be incorporated into the casing 550. In each case, the non-polymeric VSD material 505 may be incorporated so as to couple with conductive elements, such as trace leads, when voltage exceeding the characteristic voltage is present. Thus, the non-polymeric VSD material 505 is a conductive element in the presence of a specific voltage condition.

With respect to any of the applications described herein, device 500 may be a display device. For example, component 540 may correspond to an LED or LED array that illuminates from the substrate 510. The positioning and configuration of the VSD material 505 on substrate 510 may be selective to accommodate the electrical leads, terminals (i.e. input or outputs) and other conductive elements that are provided with, used by or incorporated into the light-emitting device. As an alternative, the VSD material may be incorporated between the positive and negative leads of the LED device, apart from a substrate. Still further, one or more embodiments provide for use of organic LEDs, in which case VSD material may be provided, for example, underneath an organic light-emitting diode (OLED).

With regard to LEDs and other light emitting devices, any of the embodiments described in U.S. patent application Ser. No. 11/552,289 (which is incorporated by reference herein) may be implemented with non-polymeric VSD material such as formulated and described with an embodiment of FIG. 1 or FIG. 2.

Alternatively, the device 500 may correspond to a wireless communication device, such as a radio-frequency identification device. With regard to wireless communication devices such as radio-frequency identification devices (RFID) and wireless communication components, VSD material may protect the component 540 from, for example, overcharge or ESD events. In such cases, component 540 may correspond to a chip or wireless communication component of the device. Alternatively, the use of non-polymeric VSD material 505 may protect other components from charge that may be caused by the component 540. For example, component 540 may correspond to a battery, and the non-polymeric VSD material 505 may be provided as a trace element on a surface of the substrate 510 to protect against voltage conditions that arise from a battery event. Any composition of non-polymeric VSD material in accordance with embodiments described herein (e.g. See FIG. 1 or FIG. 2) may be implemented for use as VSD material for device and device configurations described in U.S. patent application Ser. No. 11/552,222 (incorporated by reference herein), which describes numerous implementations of wireless communication devices which incorporate VSD material.

As an alternative or variation, the component 540 may correspond to, for example, a discrete semiconductor device. The non-polymeric VSD material 505 may be integrated with the component, or positioned to electrically couple to the component in the presence of a voltage that switches the material on.

Still further, device 500 may correspond to a packaged device, or alternatively, a semiconductor package for receiving a substrate component. The non-polymeric VSD material 505 may be combined with the casing 550 prior to substrate 510 or component 540 being included in the device.

FIG. 6 illustrates a wafer substrate device utilizing non-polymeric VSD material for transient electrical protection, according to an embodiment. The wafer substrate device 600 includes a wafer substrate layer 610, an integrated circuit layer 620, and a ceiling layer 630. The ceiling layer 630 is the exterior most layer prior to passivation or sealing of the wafer substrate device. Additional sealing layers may be provided on the ceiling layer 630. Typically, electrical contact elements 632 (such as solder bumps) are electrically connected to contact elements 634 at the ceiling layer to enable electrical contact outside of the wafer substrate device. In the particular configuration shown, the electrical contact element 632 (e.g. solder bumps) is a grounding element that connects to a grounding plane 640 via the electrical contact element 634 and embedded grounding plane 642. Other vias, grounding planes and configurations may be employed in wafer and substrate devices. Other solder bumps, for example, may provide electrical interconnectivity with non-grounding components of the wafer substrate device. In the configuration shown, non-polymeric VSD material 650 is deposited between electrically protected elements 652 and the electrical contacts 634 to ground. In the absence of a transient electrical event, the non-polymeric VSD material 650 maintains electrical isolation of protected elements 652 from the electrical contacts 634. During a transient electrical event, the non-polymeric VSD material 650 switches into a conductor state and connects the protected element 652 to ground.

The voltage at which the VSD material 650 switches into the conduct of state may be one of design. Accordingly, the material used for the varistor (or other non-polymeric VSD material), as well as other characteristics (e.g. clamp voltage, triggering voltage, leakage) such as its thickness, is selected based on characteristics of its granularized form (e.g. after deposition, such as described by FIG. 1 and FIG. 2).

Numerous variations are possible to an embodiment such as shown by FIG. 6. For example, the non-polymeric VSD material 650 may be deposited onto the wafer substrate at an alternative and prior fabrication step, so that the VSD material 650 is embedded within, for example, the integrated circuit layer.

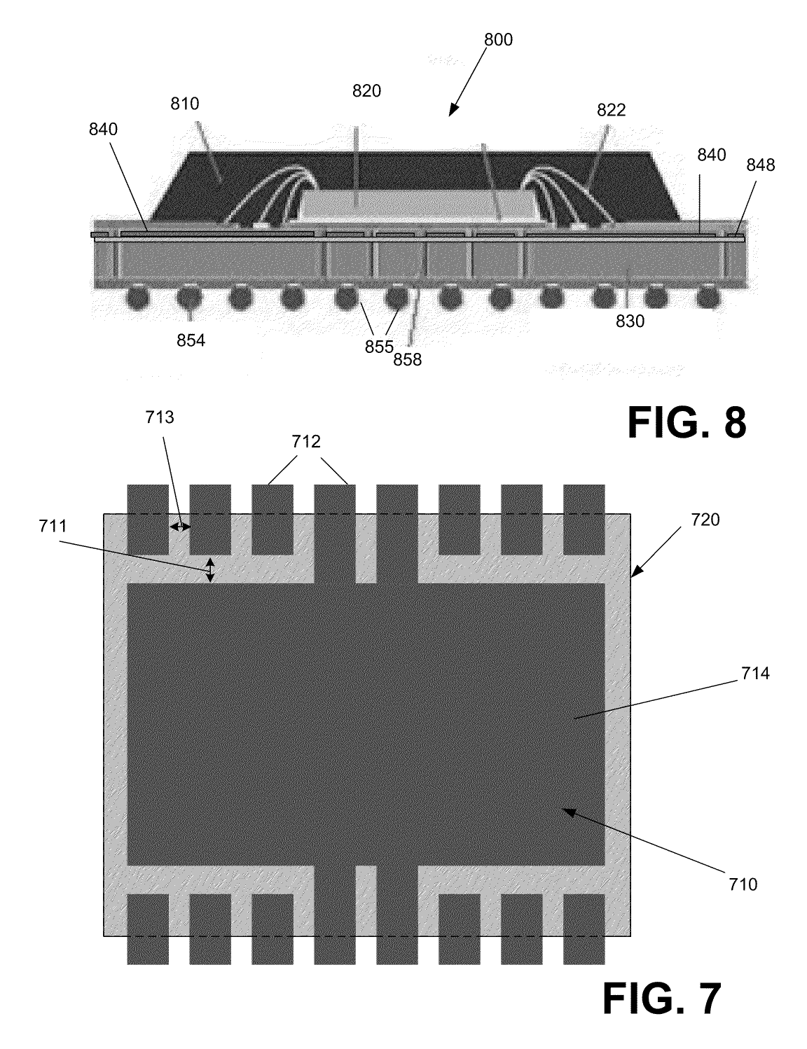

FIG. 7 is a top view of a package portion of a discrete device with a lead frame design, which incorporates non-polymeric VSD material as a protected element against transient electrical events, according to an embodiment. A package 710 is used to house a substrate device (such as shown by FIG. 8). A die (not shown) may be adhered art otherwise attached to a center portion of package 710. In one embodiment, non-polymeric varistor material is deposited as a continuous layer 720 about a periphery of the package 710. The layer spans lead frame portions 712 and center portion 714 of the package 710. When the device that uses the package 710 is complete, the gaps between the lead frame portions 712 and center portion 714 (represented by 711 and 713) can form conductive pathways that ground the interior or connected electrical elements of the device using the package 710 or its lead frame portions 712.

FIG. 8 illustrates a discrete device using a lead frame structure, having an integrated layer of non-polymeric VSD material, according to an embodiment. A device 800 includes a package 810 having a die 820 and wiring 822 that extends from the die to the lead frames. The die 820 may sit on a substrate 830 that includes an integrated layer of non-polymeric VSD material 840. The non-polymeric VSD material 840 may connect to a grounding plane 848, which can underlie the VSD material 840. In the implementation shown, the non-polymeric VSD is provided near the surface, to electrically bridge protective gaps that ground elements when a transient electrical event occurs. In many device designs, solder balls 854-855 (or other electrical contact elements) are used for external electrical connectivity, including ground (e.g. solder balls 854). Vias 858 may extend connectivity between the die 820 and the solder balls 854-855. For example, a grounding path may be formed between grounding solder balls 855, grounding via 858 and the non-polymeric VSD material 840 (when in the conduct of state). The non-polymeric VSD material 840 may be formed from a varistor such as described with an embodiment of FIG. 1 or FIG. 2. When a transient electrical event occurs, the non-polymeric VSD material 840 may switch into conductive state, thus electrically connecting the protected material to a grounding element.

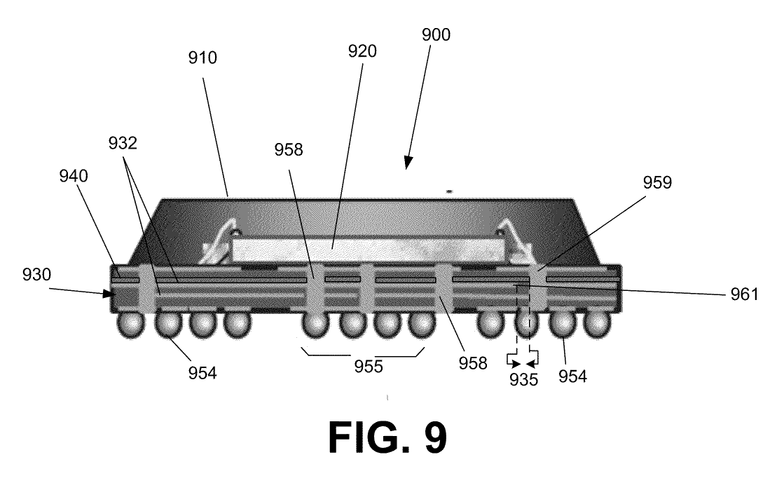

FIG. 9 illustrates a discrete device, having an integrated and embedded layer of non-polymeric VSD material, according to an embodiment. A device 900 includes a package 910 having a die 920 that sits on a mufti-layered substrate 930 having multiple electrical contact layers 932 and interconnecting vias 958 that includes an integrated layer of non-polymeric VSD material 940. The non-polymeric VSD material 940 may connect to a grounding element. In the implementation shown, the solder balls 954 and 955 (ground) are used for external electrical connectivity. Other connective elements may be formed. Vias may extend connectivity between the contact layers, die and solder balls 954, 955. For example, interior layers 932 of the substrate 930 (which may connect to the die 920) may be connected to ground within the substrate 930 at the gap 935 between the via 959 and the grounding plane 961. The non-polymeric VSD material 940 overlays the gap 935, and serves as an electrical bridge when a transient electrical event occurs. When in the conduct of state, the non-polymeric VSD material 940 electrically connects the via 959 (which connects to electrical elements and/or the die 920) to ground by way of the grounding via 958 and solder balls 955.

According to some embodiments, the non-polymeric VSD material 940 may be formed from a varistor such as described with an embodiment of FIG. 1 or FIG. 2. When a transient electrical event occurs, the non-polymeric VSD material 940 may switch into conductive state, thus electrically connecting the protected material to a grounding element.

Although illustrative embodiments have been described in detail herein with reference to the accompanying drawings, variations to specific embodiments and details are encompassed herein. It is intended that the scope of the invention is defined by the following claims and their equivalents. Furthermore, it is contemplated that a particular feature described, either individually or as part of an embodiment, can be combined with other individually described features, or parts of other embodiments. Thus, absence of describing combinations should not preclude the inventor(s) from claiming rights to such combinations.

What is claimed:

1. A non-polymeric voltage switchable dielectric (VSD) material comprising substantially of a grain structure formed from only a single compound.

2. The non-polymeric VSD material of claim 1, wherein the specific compound corresponds to one of zinc oxide, bismuth oxide, tungsten oxide, or cadmium telluride.

3. A substrate device comprising:
a metal layer;
a layer of non-polymeric voltage switchable dielectric (VSD) material;
wherein the layer of non-polymeric VSD material is formed on the metal layer.

4. The substrate device of claim 3, wherein the non-polymeric VSD material is comprised substantially of a grain structure formed from only a single compound

5. The substrate device of claim 4, wherein the metal layer includes at least one of copper, silver, nickel, gold, or chrome.

6. The substrate device of claim 4, wherein the non-polymeric VSD material is comprised purely of the single compound.

7. The substrate device of claim 4, wherein the non-polymeric VSD material is formed from one of zinc oxide, bismuth oxide, tungsten oxide, or cadmium telluride.

8. The substrate device of claim 3, wherein the non-polymeric VSD material is formed as an embedded layer within the substrate device.

9. A substrate device comprising:
one or more conductive layers;
a layer of non-polymeric voltage switchable dielectric (VSD) material;
wherein the layer of non-polymeric VSD material is formed on the metal layer; and
wherein the layer of non-polymeric VSD material is positioned to bridge a gap between one or more electrical elements of the one or more conductive layers and a grounding element.

10. The substrate device of claim 9, wherein the non-polymeric VSD material is positioned to horizontally bridge the gap between the one or more electrical elements and the grounding element.

11. The substrate device of claim 10, wherein the grounding element includes a via that extends vertically as part of a grounding path.

12. The substrate device of claim 9, wherein the non-polymeric VSD material is provided as an embedded layer within the substrate device.

13. The substrate device of claim 9, wherein the non-polymeric VSD material is positioned to vertically bridge the gap between the one or more electrical elements and the grounding element.

14. The substrate device of claim 9, wherein the non-polymeric VSD material is formed purely of one of zinc oxide, bismuth oxide, tungsten oxide, or cadmium telluride

15. The substrate device of claim 9, wherein the substrate device corresponds to a semiconductor package.

16. The substrate device of claim 9, wherein the substrate device is a wafer device.

17. The substrate device of claim 16, wherein the non-polymeric VSD material is positioned on a ceiling layer of the wafer device.

18. A method for forming a non-polymeric VSDM material on a target, the method comprising:
applying an energy beam to a varistor material in an amorphic state, so as to crystallize and peel of an exterior layer on which the energy beam is applied;
aggregating grain structures of the varistor material that formed when the varistor material crystallized and peeled off on a target location.

19. The method of claim 18, wherein applying an energy beam includes directing a laser onto the material in the amorphic state.

20. The method of claim 19, further comprising spinning the material relative to the directed laser.

21. The method of claim 18, wherein the mass is comprised of one of zinc oxide, bismuth oxide, tungsten oxide, or cadmium telluride.

22. The method of claim 18, wherein the method is performed in a vacuum.

23. A non-polymeric voltage switchable dielectric (VSD) material formed by a process that comprises:
applying an energy beam to a varistor material in an amorphic state, so as to crystallize and peel of an exterior layer on which the energy beam is applied;
aggregating grain structures of the varistor material that formed when the varistor material crystallized and peeled off on a target location.
